(19) United States
(12) Patent Application Publication
(10) Pub. No.: US 2026/0026372 A1
(43) Pub. Date: Jan. 22, 2026

(54) INTEGRATED CIRCUIT PACKAGE STRUCTURE

(71) Applicant: VIA TECHNOLOGIES, INC., New Taipei City (TW)

(72) Inventors: Wen-Yuan CHANG, New Taipei City (TW); Wei-Cheng CHEN, New Taipei City (TW); Chen-Yueh KUNG, New Taipei City (TW)

(21) Appl. No.: 19/220,650

(22) Filed: May 28, 2025

Related U.S. Application Data
(60) Provisional application No. 63/673,214, filed on Jul. 19, 2024.

(30) Foreign Application Priority Data
Dec. 24, 2024 (TW) 113150331

(51) Int. Cl. H01L 23/538; H01L 23/00; H01L 23/15

(52) U.S. Cl. CPC H01L 23/538; H01L 23/15; H01L 24/08; H01L 2224/08225

(57) ABSTRACT

An integrated circuit package structure is provided. The integrated circuit package structure includes a circuit substrate. The circuit substrate includes a core, a first inorganic dielectric layer, an organic dielectric layer and a solder mask layer. The core has a first surface and a second surface opposite each other. The first inorganic dielectric layer is disposed on the first surface of the core. The organic dielectric layer is disposed on the second surface of the core. The solder mask layer is disposed on the organic dielectric layer. The solder mask is separated from the first inorganic dielectric layer by the organic dielectric layer and the core.

### CROSS REFERENCE TO RELATED APPLICATIONS

This application claims the benefit of U.S. Provisional Application No. 63/673,214, filed Jul. 19, 2024 and priority of Taiwan Patent Application No. 113150331, filed on Dec. 24, 2024, the entirety of which are incorporated by reference herein.

### BACKGROUND OF THE INVENTION

### Field of the Invention

The present disclosure relates to an integrated circuit package structure, and, in particular, it relates to a circuit substrate of an integrated circuit package structure.

### Description of the Related Art

In the current technology used in semiconductor packaging, there has been a continuous increase in the operating frequency and power consumption of integrated circuit chips, as well as a need for multi-chip integrated packaging and multi-input/output (I/O) terminal chips. In response, the operating frequency and routing density of printed circuit boards must increase accordingly. However, in the application of high-performance computing (HPC) printed circuit boards, maintaining good reliability is becoming more and more important.

Therefore, a novel printed circuit board is needed

### BRIEF SUMMARY OF THE INVENTION

An embodiment of the disclosure provides an integrated circuit package structure. The integrated circuit package structure includes a circuit substrate. The circuit substrate includes a core, a first inorganic dielectric layer, an organic dielectric layer and a solder mask layer. The core has a first surface and a second surface which are opposite each other. The first inorganic dielectric layer is disposed on the first surface of the core. The organic dielectric layer is disposed on the second surface of the core. The solder mask layer is disposed on the organic dielectric layer. The solder mask is separated from the first inorganic dielectric layer by the organic dielectric layer and the core.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a circuit substrate of an integrated circuit package structure in accordance with some embodiments of the disclosure;

FIG. 2 is a schematic cross-sectional view of a circuit substrate of an integrated circuit package structure in accordance with some embodiments of the disclosure;

FIG. 3 is a schematic cross-sectional view of a circuit substrate of an integrated circuit package structure in accordance with some embodiments of the disclosure;

FIG. 4 is a schematic cross-sectional view of a circuit substrate of an integrated circuit package structure in accordance with some embodiments of the disclosure;

FIG. 5 is a schematic cross-sectional view of an integrated circuit package structure in accordance with some embodiments of the disclosure;

FIG. 6 is a schematic cross-sectional view of an integrated circuit package structure in accordance with some embodiments of the disclosure;

FIG. 7 is a schematic cross-sectional view of an integrated circuit package structure in accordance with some embodiments of the disclosure;

FIG. 8 is a schematic cross-sectional view of an integrated circuit package structure in accordance with some embodiments of the disclosure;

FIG. 9 is a schematic cross-sectional view of an integrated circuit package structure in accordance with some embodiments of the disclosure; and

FIG. 10 is a schematic cross-sectional view of an integrated circuit package structure in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

2.5D integrated circuit (IC) packaging usually adopts an organic flip chip build-up substrate, and uses an interposer to connect the chip and the organic flip chip build-up substrate. The interposer is bonded to the chip via microbumps. The redistribution layers (RDLs) and vias serve as the interconnect structure between the chip and the interposer. Furthermore, an underfill is used to fill the bottom of the bonded chip. In addition, the above structure is protected by a molding compound formed by a molding process. The above molding structure is bonded to the flip chip build-up substrate through bumps. The gap between the interposer and the flip chip build-up substrate is filled with the underfill again to complete the 2.5D integrated circuit packaging.

The conventional 2.5D integrated circuit (IC) packaging has many disadvantages. For example, the conventional 2.5D integrated circuit (IC) packaging process is very complex, for example, a micro-bumping process for the chip, a bumping process for the interposer, and an underfill process for bonding chips and interposer, etc., are required. Furthermore, it is necessary to reduce the parasitic capacitance and resistance caused by the bump effect as much as possible. Furthermore, there is still a large gap between the bumps of the organic build-up layer substrate, which cannot meet the requirements of chip shrinkage. Even if the chip is disposed at correct location at the beginning, there are still problems such as chip shifting during the molding process and wafer/panel stress during thermal curing. Therefore, in this technical field, an improved circuit substrate is needed to solve the above-mentioned problems.

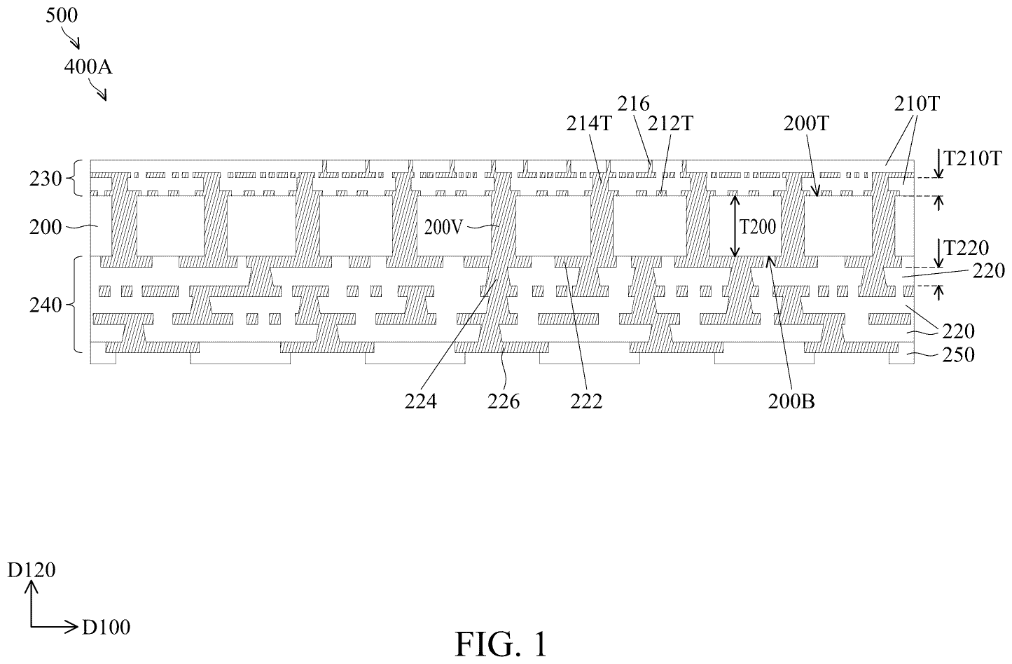

FIG. 1 is a schematic cross-sectional view of a circuit substrate 400A of an integrated circuit package structure 500 in accordance with some embodiments of the disclosure. In some embodiments, the circuit substrate 400A may include a multi-layered package substrate or an interposer. The top and bottom surfaces of the circuit substrate 400A may provide integrated circuit chips and conductive bumps mounted thereon, respectively. In the circuit substrate 400A, the conductive layer at each of the levels may include conductive lines, ground layers, power layers, or a combination thereof. The number of conductive layers of the circuit substrate 400A of the disclosure can be determined according to designs and is not limited to the disclosed embodiment. In FIG. 1 and the following figures, direction D100 is defined as a horizontal direction (also regarded as an extension direction of conductive lines and transmission lines), and direction D120 is defined as a vertical direction (also regarded as the extension direction of vias).

As shown in FIG. 1, the circuit substrate 400A may include a core 200, inorganic dielectric layers 210T, organic dielectric layers 220 and a solder mask 250.

The core 200 has a first surface 200T and a second surface 200B opposite each other. In some embodiments, the first surface 200T may be a chip-side surface, and the second surface 200B may be a conductive bump-side (or solder ball-side) surface. In some embodiments, the material of the core 200 may include glass, ceramic or glass ceramic. In the embodiment in which the material of the core 200 is glass, the coefficient of thermal expansion (CTE) of the core 200 is between 3 ppm/° C. and 9 ppm/° C.

The core 200 also has core conductive vias 200V. The core conductive via 200V passes through the core 200 Two ends of the core conductive via 200V may be aligned with the first surface 200T and the second surface 200B of the core 200, respectively. In some embodiments, the core conductive via 200V may have a solid pillar shape or a hollow pillar shape. In some embodiments, the material of the core conductive via 200V may be a conductive metal such as copper or a copper alloy. The core conductive via 200V may be formed by a drilling process and an electroplating process. In some embodiments, the core conductive via 200V may be a solid pillar or a hollow pillar filled with a plugging material. The plugging material includes resin, silver paste, or ink.

In the embodiment in which the material of the core 200 is glass, the core conductive via 200V may also be referred to as a through glass via (TGV) 200V. The through-glass vias (TGV) 200V may be formed using a drilling process including laser drilling, ultrasonic drilling, micro electrical discharge machining (μ-EDM), micro powder blasting or inductively coupled plasma reactive ion etching (ICP-RIE), a wet etching process and a subsequent electroplating process.

As shown in FIG. 1, a plurality of inorganic dielectric layers 210T stacked on each other are disposed on a first surface 200T of a core substrate 200. In some embodiments, the inorganic dielectric layer 210T closest to the core 200 is directly connected to the first surface 200T of the core 200. In other words, there is no organic dielectric layer located between the inorganic dielectric layer 210T and the first surface 200T of the core 200.

In some embodiments, the coefficient of thermal expansion (CTE) of the inorganic dielectric layer 210T is close to the CTE of the integrated circuit chip (not shown) mounted on the circuit substrate 400A. For example, when the integrated circuit chip is a silicon chip (the CTE of silicon is between 3 ppm/° C. and 5 ppm/° C.), the CTE of the inorganic dielectric layer 210T may be between 3 ppm/° C. and 5 ppm/° C. In some embodiments, the material of the inorganic dielectric layer 210T includes a silicon-containing inorganic dielectric material, such as silicon oxide (SiOₓ), silicon nitride (SiNₓ), silicon carbonitride (SiCN), silicon oxynitride (SiON), silicon carbide (SiC), or a combination thereof. Furthermore, the inorganic dielectric layer 210T may be formed using a deposition process such as plasma enhanced chemical vapor deposition (PECVD). Corresponding to the material and manufacturing process of the inorganic dielectric layer 210T, the thickness T210T of a single inorganic dielectric layer 210T may be less than or equal to 1% of the thickness T200 of the core 200.

As shown in FIG. 1, a plurality of organic dielectric layers 220 stacked on each other are disposed on the second surface 200B of the core 200. The organic dielectric layer 220 is different form the inorganic dielectric layer 210T. In this embodiment, the organic dielectric layer 220 closest to the core 200 is directly connected to the second surface 200B of the core 200. In other words, there is no inorganic dielectric layer located between the organic dielectric layer 220 and the second surface 200B of the core 200.

In some embodiments, the CTE of the organic dielectric layer 220 is between the CTE of a printed circuit board (PCB) (not shown) mounted on the circuit substrate 400A and the CTE of the core 200. For example, when the material of the core 200 is glass (the CTE of glass is between 3 ppm/° C. and 9 ppm/° C.), the CTE of the printed circuit board is between 15 ppm/° C. and 30 ppm/° C., and the CTE of the organic dielectric layer 220 may be between 9 ppm/° C. and 25 ppm/° C. In some embodiments, the material of the organic dielectric layer 220 includes bismaleimide-triazine resin. resin, BT resin), epoxy resin, phenolic resin, cyanate ester resin (CE), polycarbonate (PC), silicone elastomer, or a combination thereof. In addition, the organic dielectric layer 220 may be formed using a coating or lamination process. Corresponding to the material and manufacturing process of the organic dielectric layer 220, the thickness T220 of a single organic dielectric layer 220 may be between 1% and 15% of the thickness T200 of the core 200.

In some embodiments, the inorganic dielectric layer 210T and the organic dielectric layer 220 may have the same number of layers or different numbers of layers, and are not limited to the disclosed embodiments.

The circuit substrate 400A further includes a plurality of conductive lines 212T alternately arranged with the inorganic dielectric layers 210T, a plurality of conductive holes 214T passing through the inorganic dielectric layers 210T, and pads 216 disposed on the outermost conductive lines 212T (the conductive lines 212T farthest from the core 200). As shown in FIG. 1, the corresponding conductive lines 212T, conductive vias 214T and pads 216 are connected to each other and to the corresponding core conductive via 200V. In addition, the circuit substrate 400A further includes ground layers and power layers (not shown) surrounding the conductive lines 212T at respective levels. Furthermore, the circuit substrate 400A further includes conductive holes (not shown) connected to the ground layers and the power layers at different levels. In some embodiments, the inorganic dielectric layers 210T, the conductive lines 212T alternately arranged with the inorganic dielectric layers 210T, the conductive vias 214T passing through the inorganic dielectric layers 210T, and the pads 216 disposed on the outermost conductive lines 212T form a redistribution structure 230.

Similarly, the circuit substrate 400A further includes a plurality of conductive lines 222 alternately arranged with the organic dielectric layers 220, a plurality of conductive holes 224 passing through the organic dielectric layers 220, and pads 226 disposed on the outermost conductive lines 222 (the conductive lines 222 farthest from the core 200). As shown in FIG. 1, the corresponding conductive lines 222, conductive vias 224 and pads 226 are connected to each other and to the core corresponding conductive via 200V. In addition, the circuit substrate 400A further includes ground layers and power layers (not shown) surrounding the conductive lines 222 at respective levels. Furthermore, the circuit substrate 400A further includes conductive holes (not shown) connected to the ground layers and the power layers at different levels. In some embodiments, the organic dielectric layers 220, the conductive lines 222 alternately arranged with the organic dielectric layers 220, the conductive vias 224 passing through the organic dielectric layers 220, and the pads 226 disposed on the outermost conductive lines 222 form a redistribution structure 240. The redistribution structure 240 is connected to the redistribution structure 230 via the core conductive via 200V.

In some embodiments, corresponding to the material and manufacturing process of the inorganic dielectric layer 210T and the organic dielectric layer 220, the routing density of the redistribution structure 230 is greater than the routing density of the redistribution structure 240. Furthermore, the width and spacing of the conductive lines 222 of the redistribution structure 240 are larger than the width and spacing of the conductive lines 212T of the redistribution structure 230. For example, the ratio of the width of the conductive line 222 to the width of the conductive line 212T may be between 2.5 and 100.

As shown in FIG. 1, the solder mask 250 of the circuit substrate 400A is disposed on the organic dielectric layer 220 and covers a portion of the redistribution structure 240. Furthermore, the solder mask 250 is separated from the inorganic dielectric layer 210T by the organic dielectric layer 220 and the core 200. The solder mask layer 250 may have one or more openings, which expose portions of the pads 226 and provide locations for forming subsequent conductive bumps or solder balls (not shown).

In some embodiments, the solder mask 250 is asymmetrically formed on the first surface 200T and the second surface 200B of the core 200. As shown in FIG. 1, the solder mask layer of the circuit substrate 400A is a single solder mask layer 250 formed only on the second surface 200B of the core 200. The redistribution structure 230 is not covered by any solder mask layer. In other words, the redistribution structure 230 is not disposed between the solder mask and the core 200. The surface of the pad 216 disposed on the outermost conductive line 212T is coplanar with the surface of the outermost inorganic dielectric layer 210T.

In some embodiments, the solder mask 250 may include a solder mask material such as green paint, or an insulating material including polyimide, Ajinomoto build-up film (ABF film), epoxy resin, acrylic resin or a composite of the former two, or polypropylene (PP). The solder mask layer 250 may be formed by coating, printing, pasting, laminating, or other applicable processes.

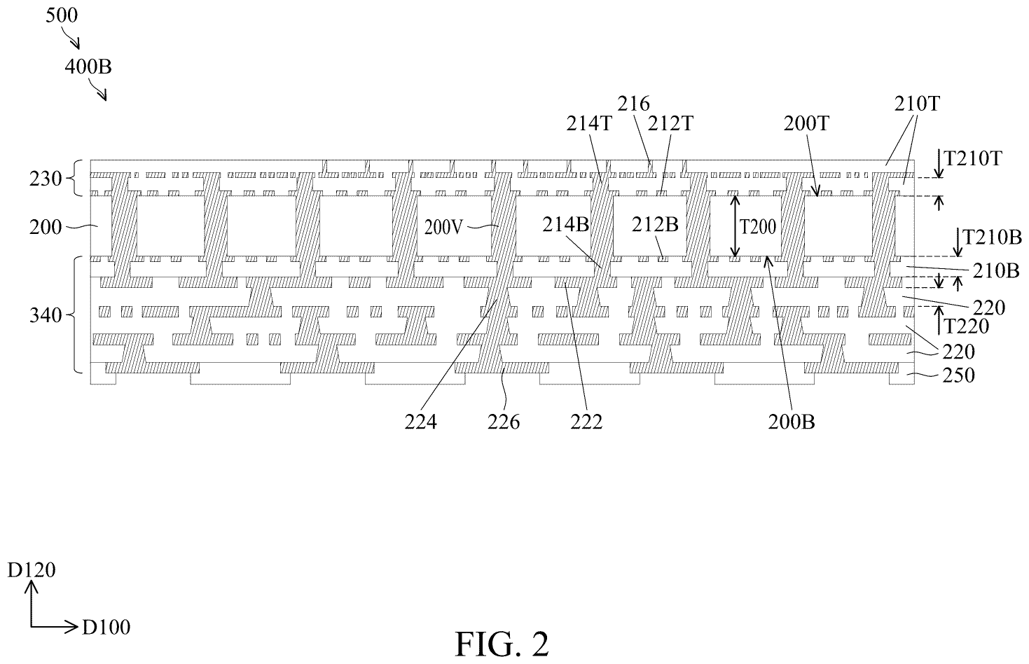

FIG. 2 is a schematic cross-sectional view of a circuit substrate 400B of an integrated circuit package structure 500 (including integrated circuit package structures 500A, 500B, 500C, 500D, 500E, and 500F in the following figures) in accordance with some embodiments of the disclosure, in which the reference numbers the same or similar to those in FIG. 1 denote the same or similar elements. At least one difference between the circuit substrate 400A (FIG. 1) and the circuit substrate 400B (FIG. 2) is that the inorganic dielectric layer of the circuit substrate 400B is formed on the opposite surfaces of the core.

As shown in FIG. 2, the circuit substrate 400B further includes an inorganic dielectric layer 210B. The inorganic dielectric layer 210B is disposed on the second surface 200B of the core 200. In addition, the inorganic dielectric layer 210B is disposed between the core 200 and the organic dielectric layer 220. In this embodiment, the top surface and the bottom surface of the inorganic dielectric layer 210B are directly connected to the second surface 200B of the core 200 and the organic dielectric layer 220 respectively. In some embodiments, the CTE of the inorganic dielectric layer 210B may be between 3 ppm/° C. and 5 ppm/° C. The inorganic dielectric layer 210T and the inorganic dielectric layer 210B may include the same or similar materials. In some embodiments, the thickness T210B of a single inorganic dielectric layer 210B may be less than or equal to 1% of the thickness T200 of the core 200. The thickness T210T of a single inorganic dielectric layer 210T may be the same as the thickness T210B of a single inorganic dielectric layer 210B. Alternatively, the thickness T210T of a single inorganic dielectric layer 210T may be different from the thickness T210B of a single inorganic dielectric layer 210B. In some embodiments, multiple build-up processes may be used to simultaneously form the inorganic dielectric layers 210T and 210B having the same number of layers and symmetrical each other on opposite sides of the core 200. Alternatively, multiple build-up processes may be used to form different numbers of inorganic dielectric layers 210T and inorganic dielectric layers 210B on opposite sides of the core substrate 200.

The circuit substrate 400B further includes a plurality of conductive lines 212B disposed between the core 200 and the inorganic dielectric layer 210B and a plurality of conductive holes 214B passing through the inorganic dielectric layer 210B. In some embodiments, the conductive lines 212T disposed on the inorganic dielectric layer 210T and the conductive lines 212B disposed on the inorganic dielectric layer 210B may have the same width and spacing. The ratio of the width of the conductive lines 222 disposed on the organic dielectric layer 220 to the width of the conductive lines 212B may be between 2.5 and 100.

As shown in FIG. 2, the corresponding conductive lines 212B and conductive vias 214B are connected to each other and to the corresponding core conductive via 200V, conductive lines 222A, conductive vias 224 and pads 226. In this embodiment, the inorganic dielectric layer 210B, the conductive lines 212B, the conductive vias 214B, the organic dielectric layers 220, the conductive lines 222, the conductive vias 224 and the pads 226 disposed on the second surface 200B of the core 200 may collectively form a redistribution structure 340. The redistribution structure 340 may be connected to the redistribution structure 230 through the core conductive vias 200V. In some embodiments, the routing density of the redistribution structure 230 is greater than the routing density of the redistribution structure 340.

The circuit substrates 400A and 400B of the integrated circuit package structure 500 may use a glass substrate having a CTE close to that of silicon as the core 200. Furthermore, the dielectric layer of the die-side redistribution structure (the redistribution structure 230) and the dielectric layer located at the outer side of the conductive bump-side (or solder ball-side) redistribution structure (the redistribution structure 240 in FIG. 1 and redistribution structure 340 in FIG. 2) have different CTE. For example, the dielectric layer of the die-side redistribution structure (the redistribution structure 230) is an inorganic dielectric layer (the inorganic dielectric layer 210T). The CTE of the inorganic dielectric layer is similar to the CTE of the integrated circuit chip (not shown) mounted on the circuit substrate. Therefore, the CTE of the inorganic dielectric layer can be more matched with the CTE of the integrated circuit chip. Furthermore, the dielectric layer located at the outer side of the conductive bump-side (or the solder ball-side) redistribution structure (the redistribution structure 240, 340) is an organic dielectric layer (the organic dielectric layer 220). The CTE of the organic dielectric layer is between the CTE of the core 200 and the CTE of the printed circuit board, so as to serve as a coefficient of thermal expansion (CTE) buffer layer between the integrated circuit chip and the printed circuit board. When the IC package structure 500 is mounted on the printed circuit board, the organic dielectric layer may avoid reliability issues caused by CTE mismatch between the IC package structure 500 and the printed circuit board. Furthermore, the die-side redistribution structure (the redistribution structure 230) may have a denser routing density (similar to that of an integrated circuit die). The conductive bump-side (or solder ball-side) redistribution structure (the redistribution structures 240, 340) may have a sparser routing density (similar to that of a printed circuit board).

In the embodiment of the circuit substrate 400B, inorganic dielectric layers (the inorganic dielectric layers 210T, 210B) may be disposed on both the chip-side surface (the first surface 200T) and the conductive bump-side (or solder ball-side) surface (the second surface 200B) of the core 200. Therefore, the dielectric layers of the conductive bump-side (or solder ball-side) redistribution structure (the redistribution structure 340) include the inorganic dielectric layer 210B close to the core 200 and the organic dielectric layer (the organic dielectric layer 220) close to the solder mask 250.

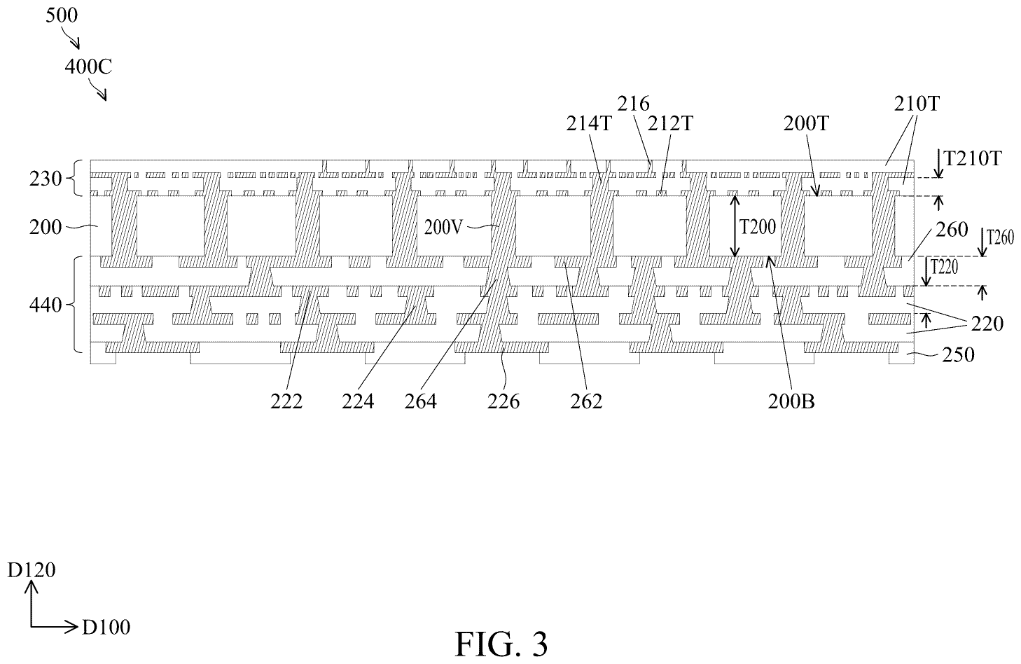

FIG. 3 is a schematic cross-sectional view of a circuit substrate 400C of the integrated circuit package structure 500 in accordance with some embodiments of the disclosure, in which the reference numbers the same or similar to those in FIG. 1 denote the same or similar elements. At least one difference between the circuit substrate 400A (FIG. 1) and the circuit substrate 400C (FIG. 3) is that the circuit substrate 400C further includes a stress-release dielectric layer 260.

As shown in FIG. 3, the stress-release dielectric layer 260 is disposed on the second surface 200B of the core 200. In addition, the stress-release dielectric layer 260 is disposed between the core 200 and the organic dielectric layer 220. In this embodiment, the stress-release dielectric layer 260 is directly connected to the second surface 200B of the core 200. The stress-release dielectric layer 260 is used to release stress and resist degradation of the circuit substrate 400C during being put into service (e.g., bonding to a chip and/or a printed circuit board). In some embodiments, the material of the stress-release dielectric layer 260 may include a hybrid organic-inorganic polymer (HOIP) material. In some embodiments, the hybrid organic-inorganic polymer material has an inorganic portion including, for example, a silicon-oxide chain. The material of the stress-release dielectric layer 260 may further include an organic polymer portion including, for example, a carbon chain. For example, the material of the stress-release dielectric layer 260 may include polycarbonate (PC), silicone elastomer, layered silicate, nanoparticles, other appropriate hybrid organic-inorganic polymer materials, or a combination thereof. In some embodiments, the CTE of the stress-release dielectric layer 260 may be between the CTE of the inorganic dielectric layer 210T and the CTE of the organic dielectric layer 220. Also, the CTE of the stress-release dielectric layer 260 is mainly determined by the CTE of the organic polymer portion. For example, the CTE of the stress-release dielectric layer 260 may be between 9 ppm/° C. and 25 ppm/° C. Furthermore, a deposition process may be used to form the stress-release dielectric layer 260. In some embodiments, corresponding to the material and manufacturing process of the stress-release dielectric layer 260, the thickness T260 of a single stress-release dielectric layer 260 may be between 1% and 15% of the thickness T200 of the core 200. The thickness T260 of a single stress-release dielectric layer 260 may be the same as the thickness T220 of a single organic dielectric layer 220. Alternatively, the thickness T260 of a single stress-release dielectric layer 260 may be different from the thickness T220 of a single organic dielectric layer 220.

The circuit substrate 400C further includes a plurality of conductive lines 262 disposed between the core 200 and the stress-release dielectric layer 260 and a plurality of conductive holes 264 passing through the stress-release dielectric layer 260. In some embodiments, corresponding to the material and manufacturing process of the stress-release dielectric layer 260, the conductive lines 262 disposed on the stress-release dielectric layer 260 and the conductive lines 222 disposed on the organic dielectric layer 220 may have the same width and spacing. Furthermore, the width and the spacing of the conductive lines 262 are greater than the width and the spacing of the conductive lines 212T disposed on the inorganic dielectric layer 210T. For example, the ratio of the width of the conductive line 262 to the width of the conductive line 212T may be between 2.5 and 100.

As shown in FIG. 3, the corresponding conductive lines 262 and conductive vias 264 are connected to each other and to the corresponding core conductive vias 200V, conductive lines 222, conductive vias 224 and pads 226. In this embodiment, the stress-release dielectric layer 260, the conductive lines 262, the conductive vias 264, the organic dielectric layers 220, the conductive lines 222, the conductive vias 224 and the pads 226 disposed on the second surface 200B of the core 200 may collectively form a redistribution structure 440. The redistribution structure 440 may be connected to the redistribution structure 230 through the core conductive vias 200V. In some embodiments, the routing density of the redistribution structure 230 is greater than the overall routing density of the redistribution structure 440.

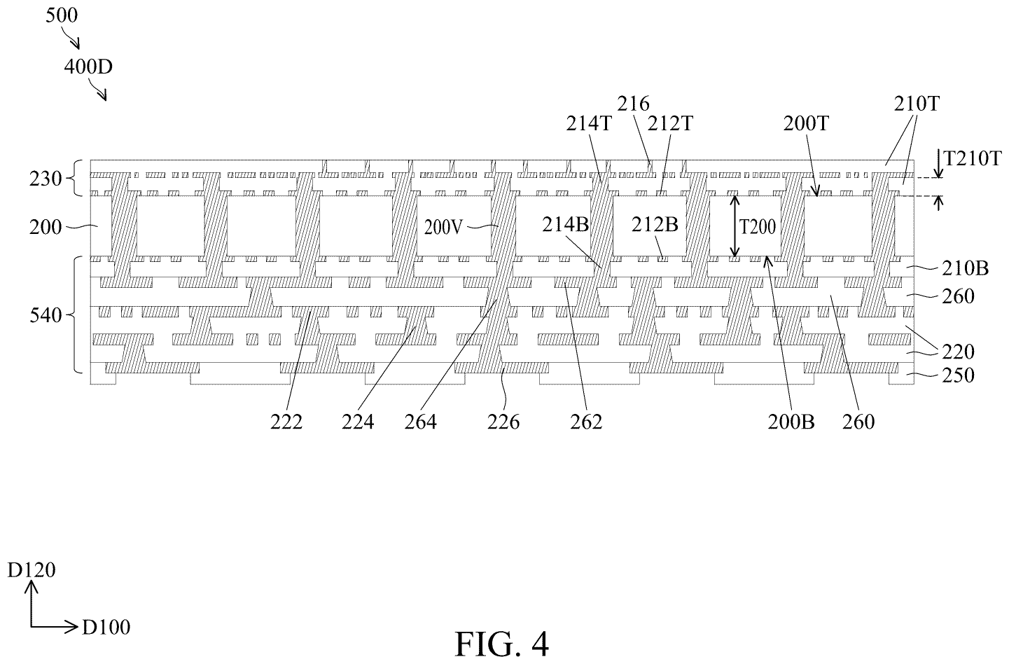

FIG. 4 is a schematic cross-sectional view of a circuit substrate 400D of the integrated circuit package structure 500 in accordance with some embodiments of the disclosure, in which the reference numbers the same or similar to those in FIGS. 1 to 3 denote the same or similar elements. At least one difference between the circuit substrate 400B (FIG. 2) and the circuit substrate 400D (FIG. 4) is that the circuit substrate 400D further includes a stress-release dielectric layer 260.

As shown in FIG. 4, the inorganic dielectric layer 210B is disposed on the second surface 200B of the core substrate 200. In addition, the stress-release dielectric layer 260 is disposed between the inorganic dielectric layer 210B and the organic dielectric layer 220. In this embodiment, the top surface and the bottom surface of the stress-release dielectric layer 260 are directly connected to the inorganic dielectric layer 210B and the organic dielectric layer 220, respectively.

As shown in FIG. 4, the conductive lines 262 covered by the stress-release dielectric layer 260 and the corresponding conductive vias 264 passing through the stress-release dielectric layer 260 are connected to each other and to the corresponding core conductive vias 200V, conductive lines 212B, conductive vias 214B, conductive lines 222, conductive vias 224 and pads 226. In this embodiment, the inorganic dielectric layer 210B, the conductive lines 212B, the conductive holes 214B, the stress-release dielectric layer 260, the conductive lines 262, the conductive holes 264, the organic dielectric layers 220, the conductive lines 222, the conductive holes 224 and the pads 226 disposed on the second surface 200B of the core 200 may collectively form a redistribution structure 540. The redistribution structure 540 may be connected to the redistribution structure 230 through the core conductive vias 200V. In some embodiments, the routing density of the redistribution structure 230 is greater than the routing density of the redistribution structure 540.

The circuit substrates 400C and 400D of the integrated circuit package structure 500 further include a stress-release dielectric layer 260 disposed on the conductive bump-side (or solder ball-side) surface (the second surface 200B). In addition, the stress-release dielectric layer 260 is disposed between the core 200 and the organic dielectric layer 220. When the circuit substrates 400C, 400D are bonded to the chip and/or printed circuit board, the stress-release dielectric layer 260 may serve as a buffer layer between the core 200 and the organic dielectric layer 220 and absorb the bonding stress to further enhance the reliability of the integrated circuit package structure 500.

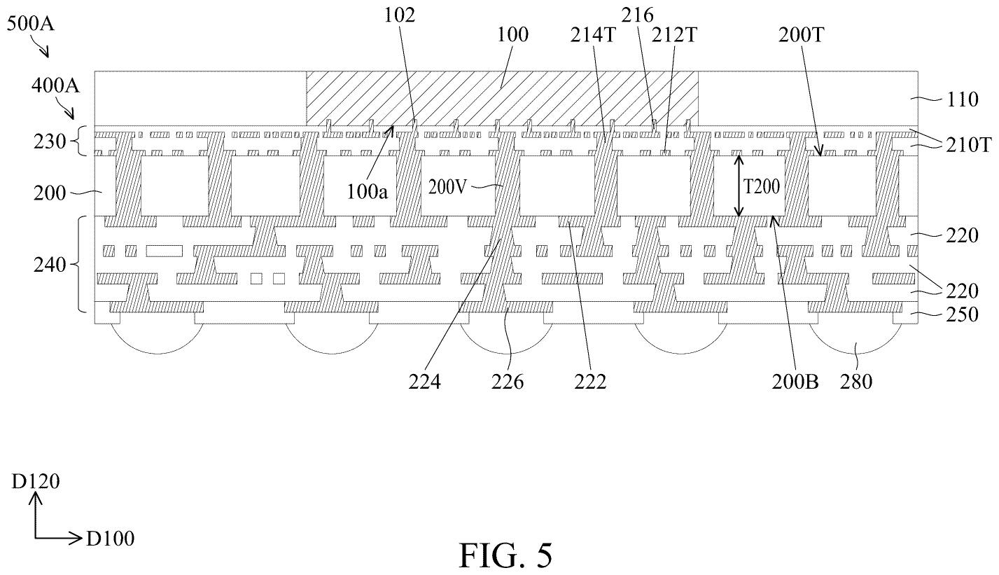

FIG. 5 is a schematic cross-sectional view of an integrated circuit package structure 500A in accordance with some embodiments of the disclosure, in which the reference numbers the same or similar to those in FIGS. 1 to 4 denote the same or similar elements.

As shown in FIG. 5, the integrated circuit package structure 500A includes a circuit substrate 400A, a chip 100 and conductive bumps (or solder balls) 280.

The chip 100 is disposed on the inorganic dielectric layer 210T of the redistribution structure 230. In some embodiments, the chip 100 may include a single chip of a CPU chip, a logic chip, a graphics processing chip, an input/output chip, a memory chip, a baseband chip, a radio frequency chip, or a special function integrated circuit chip. Alternatively, the chip 100 may also include a chiplet composed of the above-mentioned single chip. In some embodiments, an active surface 100a of the chip 100 has a plurality of chip pads 102 and a dielectric layer (not shown) surrounding the chip pads 102. The surfaces of the chip pads 102 and the surface of the dielectric layer surrounding the chip pads 102 are coplanar with each other. In some embodiments, the material of the chip pad 102 may include a conductive metal or alloy such as copper.

When the dielectric layer of the die-side redistribution structure (the redistribution structure 230) of the circuit substrate is formed by an inorganic dielectric layer (the inorganic dielectric layer 210T), and the pad 216 of the redistribution structure 230 is formed by copper, the die-side redistribution structure (the redistribution structure 230) may be directly bonded to the chip by hybrid bonding. Specifically, the chip pads 102 of the chip 100 are directly bonded to the corresponding pads 216 of the redistribution structure 230. In addition, the dielectric layer surrounding the chip pads 102 is directly bonded to the outermost inorganic dielectric layer 210T of the redistribution structure 230. In this embodiment, there is no solder mask, conductive bump (e.g., solder bump) and underfill between the chip 100 and the redistribution structure 230. In addition, the chip pads 102 are not covered by the underfill.

The conductive bumps (or solder balls) 280 are located above the second surface 200B of the circuit substrate 400A and disposed on the organic dielectric layer 220. In addition, the conductive bumps (or solder balls) 280 pass through the solder mask 250 to connect to the pad 226 of the redistribution structure 240. The chip pads 102 of the chip 100 may be coupled to corresponding conductive bumps (or solder balls) 280 through the redistribution structure 230, the core conductive vias 200V, and the redistribution structure 240.

The integrated circuit package structure 500A further includes a dielectric layer 110. The dielectric layer 110 is disposed on the redistribution structure 230 and covers side surfaces of the chip 100. The dielectric layer 110 may be used to protect the chip 100. In some embodiments, the CTE of the dielectric layer 110 may be similar to that of silicon, for example, approximately between 3 ppm/° C. and 5 ppm/° C.

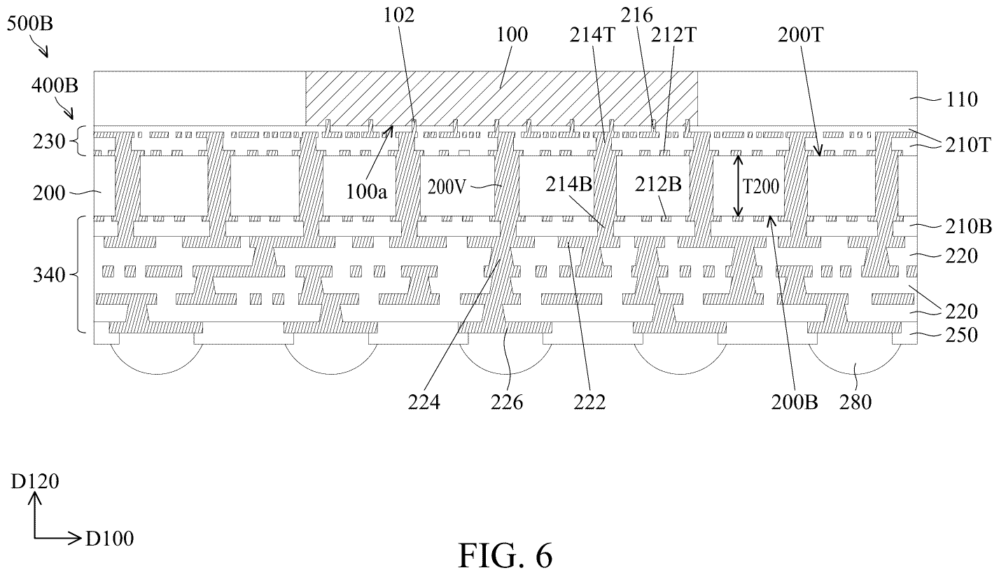

FIG. 6 is a schematic cross-sectional view of an integrated circuit package structure 500B in accordance with some embodiments of the disclosure, in which the reference numbers the same or similar to those in FIGS. 1 to 5 denote the same or similar elements.

As shown in FIG. 6, the integrated circuit package structure 500B includes a circuit substrate 400B, a chip 100 and conductive bumps (or solder balls) 280. The chip 100 may be hybrid-bonded to the redistribution structure 230 of the circuit substrate 400B. “Hybrid-bonded” means the chip pads 102 of the chip 100 are directly bonded to the corresponding pads 216 of the redistribution structure 230. Therefore, the chip pads 102 of the chip 100 may be coupled to the corresponding conductive bumps (or solder balls) 280 through the redistribution structure 230, the core conductive vias 200V, and the redistribution structure 340.

In other embodiments, the chip 100 may also be hybrid-bonded to the redistribution structure 230 of the circuit substrate 400C (FIG. 3) or the circuit substrate 400D (FIG. 4). The conductive bumps (or solder balls) 280 may be connected to the pads 226 of the redistribution structure 240 of the circuit substrate 400C (FIG. 3) or the circuit substrate 400D (FIG. 4).

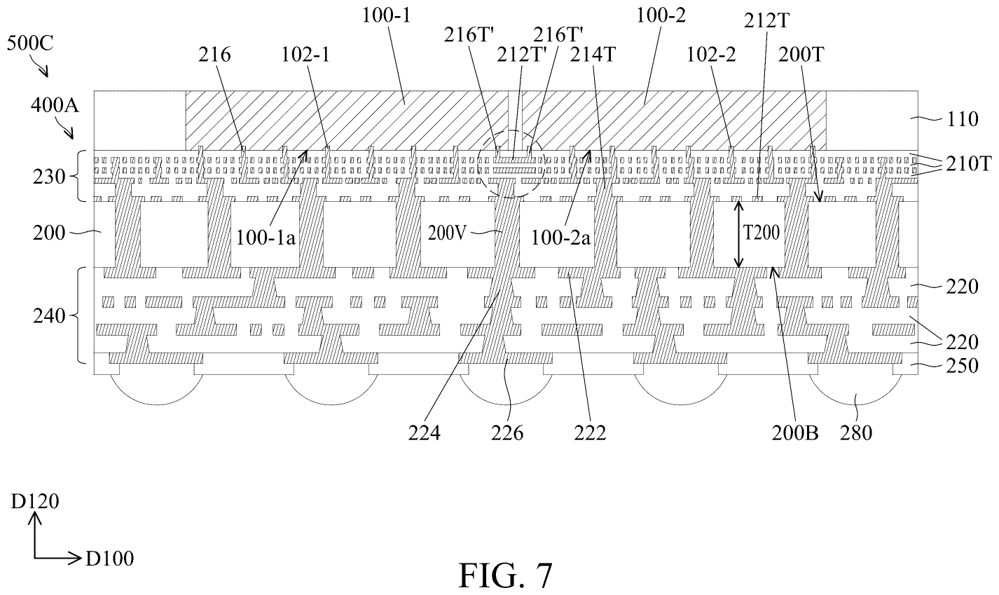

FIG. 7 is a schematic cross-sectional view of an integrated circuit package structure 500C in accordance with some embodiments of the disclosure, in which the reference numbers the same or similar to those in FIGS. 1 to 6 denote the same or similar elements. At least one difference between the integrated circuit package structure 500A (FIG. 5) and the integrated circuit package structure 500C is that the integrated circuit package structure 500C includes chips 100-1 and 100-2.

As shown in FIG. 7, the integrated circuit package structure 500C includes a circuit substrate 400A, the chip 100-1, the chip 100-2, and conductive bumps (or solder balls) 280. The chip 100-1 and the chip 100-2 are disposed side by side on the inorganic dielectric layer 210T of the redistribution structure 230 along the direction D100. In some embodiments, active surfaces 100-1a and 100-2a of the chips 100-1 and 100-2 have a plurality of chip pads 102-1 and 102-2 and dielectric layers (not shown) surrounding the chip pads 102-1 and 102-2. In this embodiment, the chips 100-1 and 100-2 are hybrid-bonded to the redistribution structure 230. Specifically, the chip pads 102-1 and 102-2 of the chips 100-1 and 100-2 are directly bonded to different pads 216 of the redistribution structure 230, respectively. The dielectric layers surrounding the chip pads 102-1 and 102-2 are directly bonded to the outermost inorganic dielectric layer 210T of the redistribution structure 230. In this embodiment, there are no solder mask layers, conductive bumps (such as solder bumps) and underfill between the chips 100-1, 100-2 and the redistribution structure 230. In addition, the chip pads 102-1, 102-2 are not covered by the underfill.

According to the aforementioned connection method, the chip pads 102-1 of the chip 100-1 and the chip pads 102-2 of the chip 100-2 may be coupled to different conductive bumps (or solder balls) 280 through the redistribution structure 230, the core conductive vias 200V, and the redistribution structure 240, respectively.

In addition, in this embodiment, the chip 100-1 is coupled to the chip 100-2 via the redistribution structure 230. In detail, the chip pads 102-1 of the chip 100-1 and the chip pads 102-2 of the chip 100-2 that are close to each other may be coupled to each other through conductive lines 212T′ and the pads 216T′. Two ends of the conductive line 212T′ may be connected to corresponding pads 216T′ respectively. Furthermore, the conductive lines 212T′ and the pads 216T′ will not be coupled to the conductive bumps 280 through the core conductive vias 200V and the redistribution structure 240.

As shown in FIG. 7, the dielectric layer 110 of the integrated circuit package structure 500C covers the side surfaces of the chips 100-1 and 100-2 and fills the gap between the chips 100-1 and 100-2.

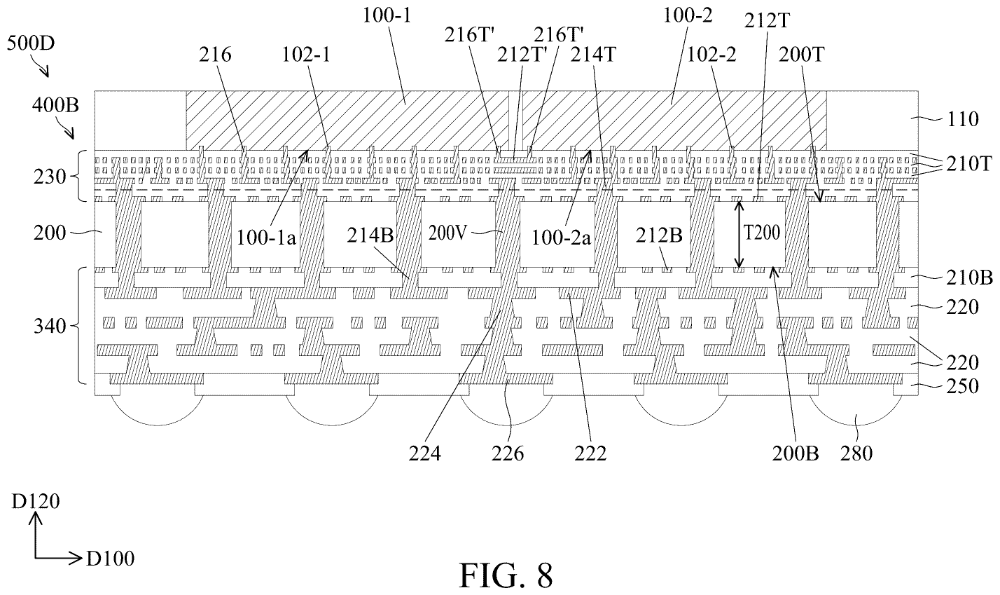

FIG. 8 is a schematic cross-sectional view of an integrated circuit package structure 500D in accordance with some embodiments of the disclosure, in which the reference numbers the same or similar to those in FIGS. 1 to 7 denote the same or similar elements. At least one difference between the integrated circuit package structure 500B (FIG. 6) and the integrated circuit package structure 500D is that the integrated circuit package structure 500D includes chips 100-1 and 100-2.

In this embodiment, the chips 100-1 and 100-2 are hybrid-bonded to the redistribution structure 230. The chip pads 102-1 and 102-2 of the chips 100-1 and 100-2 are directly bonded to different pads 216 of the redistribution structure 230, respectively. Therefore, the chip pads 102-1 of the chip 100-1 and the chip pads 102-2 of the chip 100-2 may be coupled to different conductive bumps (or solder balls) 280 through the redistribution structure 230, the core conductive vias 200V, and the redistribution structure 340, respectively.

In addition, in this embodiment, the chip pads 102-1 of the chip 100-1 are coupled to the adjacent chip pads 102-2 of the chip 100-2 via the conductive lines 212T′ and the pads 216T′ of the redistribution structure 230. The conductive lines 212T′ and the pads 216′ are not coupled to the conductive bumps (or solder ball) 280 through the core conductive vias 200V and the redistribution structure 240.

In other embodiments, the chip pads 102-1, 102-2 of the chips 100-1, 100-2 may also be hybrid-bonded to different pads 216 of the redistribution structure 230 of the circuit substrate 400C (FIG. 3) or the circuit substrate 400D (FIG. 4) in order to couple to different conductive bumps (or solder balls) 280. The chip pads 102-1 and 102-2 of the chips 100-1 and 100-2 may be coupled to each other via the conductive lines 212T′ and the pads 216T′ of the redistribution structure 230.

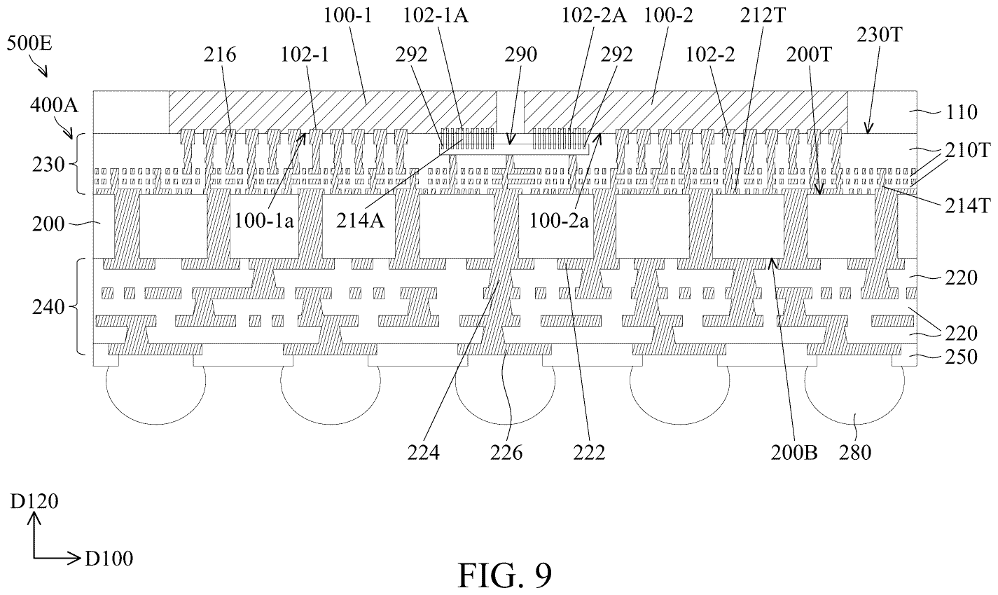

FIG. 9 is a schematic cross-sectional view of an integrated circuit package structure 500E in accordance with some embodiments of the disclosure, in which the reference numbers the same or similar to those in FIGS. 1 to 8 denote the same or similar elements. At least one difference between the integrated circuit package structure 500C (FIG. 7) and the integrated circuit package structure 500E is that the integrated circuit package structure 500E further includes a bridge element 290.

As shown in FIG. 9, the integrated circuit package structure 500E includes a circuit substrate 400A, a chip 100-1, a chip 100-2, the bridge element 290, a dielectric layer 110, and a conductive bumps (or solder balls) 280.

The chip 100-1 and the chip 100-2 are disposed side by side on the inorganic dielectric layer 210T of the redistribution structure 230. The active surface 100-1a of the chip 100-1 had a plurality of chip pads 102-1 and 102-1A and a dielectric layer (not shown) surrounding the chip pads 102-1 and 102-1A. In this embodiment, the chip pads 102-1 and 102-1A have different pitches. For example, in the chip 100-1, the pitch of the chip pads 102-1A close to the chip 100-2 is smaller than the pitch of the chip pads 102-1 away from the chip 100-2.

Similarly, the active surface 100-2a of the chip 100-2 has a plurality of chip pads 102-2 and 102-2A and a dielectric layer (not shown) surrounding the chip pads 102-2 and 102-2A. In this embodiment, the chip pads 102-2 and 102-2A have different pitches. For example, in the chip 100-2, the pitch of the chip pads 102-2A close to the chip 100-1 is smaller than the pitch of the chip pads 102-2 away from the chip 100-1. The chip pads 102-1A and 102-2A may have the same pitch.

The bridge element 290 is disposed in the inorganic dielectric layer 210T of the redistribution structure 230. Furthermore, in the direction D120, the bridge element 290 may partially overlap with the chips 100-1 and 100-2. For example, the thickness of the bridge element 290 may be smaller than the thickness of the chips 100-1 and 100-2. The outermost inorganic dielectric layer 210T of the redistribution structure 230 may have a thicker thickness so that the bridge element 290 can be buried therein and the top surface 230T of the redistribution structure 230 may maintain a flat surface to facilitate bonding with the chips 100-1 and 100-2.

As shown in FIG. 9, the bridge element 290 has a plurality of bridge pads 292. In some embodiments, the pitch of the bridge pads 292 may be equal to the pitch of the chip pads 102-1A and 102-2A. The chip pads 102-1A and 102-2A may be located directly above the corresponding bridge pads 292. In this embodiment, the bridge pads 292 may be connected to conductive structures 214A of the redistribution structure 230. The conductive structures 214A are disposed in the outermost inorganic dielectric layer 210T and are located between the chip pads 102-1A, 102-2A and the corresponding bridge pads 292. In some embodiments, the bridge element 290 may include an active element or a passive element.

In this embodiment, the chips 100-1 and 100-2 are hybrid-bonded to the redistribution structure 230. More specifically, the chip pads 102-1 of the chip 100-1 and the chip pads 102-2 of the chip 100-2 are directly bonded to different pads 216 of the redistribution structure 230, respectively.

According to the aforementioned connection method, the chip pads 102-1 of the chip 100-1 and the chip pads 102-2 of the chip 100-2 may be coupled to different conductive bumps (or solder balls) 280 through the redistribution structure 230, the core conductive vias 200V, and the redistribution structure 240.

In addition, in this embodiment, the chip 100-1 is coupled to the chip 100-2 via the bridge element 290. More specifically, the chip pads 102-1A and 102-2A in the chips 100-1 and 100-2 that are close to each other are directly bonded (hybrid bonded) to different conductive structures 214A of the redistribution structure 230, respectively. Furthermore, different conductive structures 214A are directly bonded (hybrid bonded) to the corresponding bridge pads 292. Furthermore, the bridge element 290 and the conductive structure 214A are not coupled to the conductive bump 280 through the core conductive via 200V and the redistribution structure 240.

Furthermore, the dielectric layers surrounding the chip pads 102-1 and 102-1A and the dielectric layer surrounding the chip pads 102-2 and 102-2A are directly bonded to the outermost inorganic dielectric layer 210T of the redistribution structure 230. In this embodiment, there is no solder mask, conductive bump (e.g., solder bump) or underfill between the chip pads 102-1, 102-2, 102-1A, 102-2A and the redistribution structure 230. In addition, the chip pads 102-1, 102-2, 102-1A, 102-2A are not covered by the underfill.

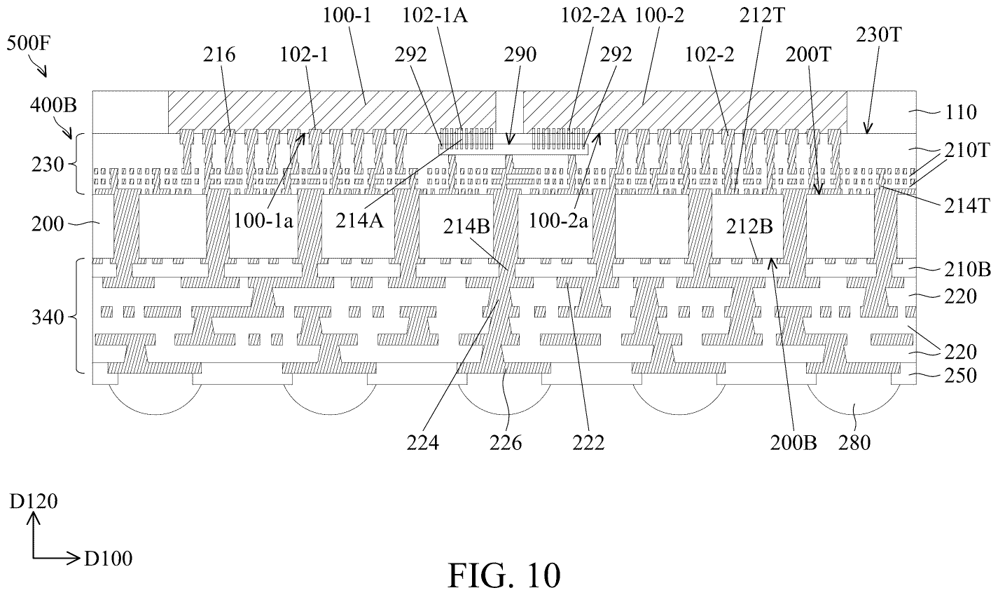

FIG. 10 is a schematic cross-sectional view of an integrated circuit package structure 500F in accordance with some embodiments of the disclosure, in which the reference numbers the same or similar to those in FIGS. 1 to 9 denote the same or similar element. At least one difference between the integrated circuit package structure 500D (FIG. 8) and the integrated circuit package structure 500F is that the integrated circuit package structure 500F further includes a bridge element 290.

As shown in FIG. 10, the integrated circuit package structure 500F includes a circuit substrate 400B, a chip 100-1, a chip 100-2, the bridge elements 290, a dielectric layer 110, and conductive bumps (or solder balls) 280.

In this embodiment, the chips 100-1 and 100-2 are hybrid-bonded to the redistribution structure 230. More specifically, the chip pads 102-1 of the chip 100-1 and the chip pads 102-2 of the chip 100-2 are directly bonded to different pads 216 of the redistribution structure 230, respectively.

According to the aforementioned connection method, the chip pads 102-1 of the chip 100-1 and the chip pads 102-2 of the chip 100-2 may be coupled to different conductive bumps (or solder balls) 280 through the redistribution structure 230, the core conductive via 200V, and the redistribution structure 340.

In addition, in this embodiment, the chip 100-1 is coupled to the chip 100-2 via the bridge element 290. Specifically, the chip pads 102-1A and 102-2A in the chips 100-1 and 100-2 that are close to each other are directly bonded (hybrid bonded) to different conductive structures 214A of the redistribution structure 230, respectively. Furthermore, different conductive structures 214A are directly bonded (hybrid bonded) to corresponding bridge pads 292 of the bridge element 290. Furthermore, the bridge element 290 and the conductive structure 214A are not coupled to the conductive bump (or solder ball) 280 through the core conductive via 200V and the redistribution structure 340.

Furthermore, the dielectric layers surrounding the chip pads 102-1 and 102-1A and the dielectric layer surrounding the chip pads 102-2 and 102-2A are directly bonded (hybrid bonded) to the outermost inorganic dielectric layer 210T of the redistribution structure 230. In this embodiment, there is no solder mask, conductive bump (e.g., solder bump) or underfill between the chip pads 102-1, 102-2, 102-1A, 102-2A and the redistribution structure 230. In addition, the chip pads 102-1, 102-2, 102-1A, 102-2A are not covered by the underfill.

In other embodiments, the chip pads 102-1 of the chip 100-1 and the chip pads 102-2 of the chip 100-2 may also be hybrid-bonded to different pads 216 of the redistribution structure 230 of the circuit substrate 400C (FIG. 3) or the circuit substrate 400D (FIG. 4) in order to couple to different conductive bumps (or solder balls) 280. Furthermore, the chip pads 102-1 of the chip 100-1 and the chip pads 102-2 of the chip 100-2 may be coupled to each other via the bridge element 290 embedded in the redistribution structure 230.

The integrated circuit package structures 500A-500F of the embodiment of the disclosure use a hybrid bonding method to directly bond the die-side redistribution structure (the redistribution structure 230) to the chip. The joint size and the thickness of the package structure can be greatly reduced. In addition, when the joint size is shrunk, the problems of adjacent conductive bumps bridging and bottom glue being unable to fill in the conventional flip chip packaging technology can be avoided. In addition, compared to the solder reflow process (the process temperature of the solder reflow process is about 240° C. to 250° C.) used in the conventional integrated circuit package structure, the hybrid bonding process applies a lower process temperature (e.g., less than or equal to 200° C.), which can significantly reduce the stress on the circuit substrate during chip bonding.

The integrated circuit package structure in accordance with some embodiments of the disclosure has the following advantages: no molding process is performed after the placement of the chip, and no molding stress issue such as chip shifting is occurred, so that the chip alignment accuracy can be maintained. The CTE of the inorganic dielectric layer of the chip-side redistribution structure is similar to that of silicon, which can improve the matching degree of the CTE of the die-side redistribution structure and the chip. The circuit substrate of the integrated circuit package structure can be hybrid-bonded to the chips through a fine-pitch bridge element without using solder balls to achieve a solid structure having a high-density input/output interface and an extremely short interconnection structure between different chips.

In the integrated circuit package structure in accordance with some embodiments of the disclosure, the die-side redistribution structure has an interconnection structure having high-density and solderless interfaces, which can assist to reduce the required circuit power consumption and realize high-performance computing applications. The cost of the bridge element for coupling different chips is lower than that of the wafer-level interposer, which can reduce the cost of the integrated circuit package structure. Compared with the conventional solder joints between a chip and a substrate, the integrated circuit package structure in accordance with some embodiments of the disclosure can significantly reduce parasitic capacitance and resistance. The die-to-substrate interconnection structure is formed without bumps (a bumpless structure), so there is no need for under-bump metallization (UBM) and micro-bump or bump processes. Furthermore, a reflow process for bonding the chip to the substrate is not required. The inorganic dielectric layer of the wafer-side redistribution structure is hybrid-bonded (directly bonded) to the dielectric layer of the chip without the need of the underfill to fill the gap between the circuit substrate and the chip. Therefore, the 2.5D integrated circuit packaging process can be greatly simplified.

The integrated circuit package structure in accordance with some embodiments of the disclosure may use a panel-level glass core, which can keep a flat surface during the thin film deposition process of forming the inorganic dielectric layer and reduce the cost due to higher throughput than wafer level process. Compared with the micro-bump and solder bump connection structure used in the conventional integrated circuit package structure, the integrated circuit package structure of the embodiment of the disclosure has fewer process steps and lower risk of yield. The integrated circuit package structure in accordance with some embodiments of the disclosure may use glass having low CTE, low dielectric constant (dk) and low loss factor (df) as the core, which is more suitable for high-speed signal transmission applications. When the material of the core substrate is glass, the flat and stiff glass surface helps to control substrate warpage and perform hybrid bonding processes. The hybrid bonding process may include a low temperature process such as a homogenized laser. The focus of the laser can be controlled to be located at the interface between the circuit substrate and the chip for local heating. In addition, an optional low temperature annealing process can be used to reduce the stress of the entire chip on the substrate.

An embodiment of the disclosure provides an integrated circuit package structure. Including a circuit substrate. The circuit substrate comprises a core, a first inorganic dielectric layer, an organic dielectric layer and a solder mask layer. The core has a first surface and a second surface which are opposite each other. The first inorganic dielectric layer is disposed on the first surface of the core. The organic dielectric layer is disposed on the second surface of the core. The solder mask layer is disposed on the organic dielectric layer. The solder mask is separated from the first inorganic dielectric layer by the organic dielectric layer and the core.

In some embodiments, the material of the core includes glass, ceramic or glass ceramic, and the CTE of the core may be between 3 ppm/° C. and 9 ppm/° C. The CTE of the inorganic dielectric layer may be between 3 ppm/° C. and 5 ppm/° C. The thickness of the inorganic dielectric layer is less than or equal to 1% of the thickness of the core. The CTE of the organic dielectric layer may be between 9 ppm/° C. and 25 ppm/° C. The thickness of the organic dielectric layer is between 1% and 15% of the thickness of the core. Furthermore, the ratio of the width of a conductive line disposed on the organic dielectric layer to the width of another conductive line disposed on the inorganic dielectric layer may be between 2.5 and 100.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit package structure, comprising:
a circuit substrate, comprising:
a core having a first surface and a second surface opposite each other;
a first inorganic dielectric layer disposed on the first surface of the core;
an organic dielectric layer disposed on the second surface of the core, wherein a material of the organic dielectric layer is different from a material of the first inorganic dielectric layer; and
a solder mask disposed on the organic dielectric layer, wherein the solder mask is separated from the first inorganic dielectric layer by the organic dielectric layer and the core.

2. The integrated circuit package structure as claimed in claim 1, wherein a CTE of the core is between 3 ppm/° C. and 9 ppm/° C.

3. The integrated circuit package structure as claimed in claim 1, wherein the material of the core includes glass, ceramic or glass ceramic.

4. The integrated circuit package structure as claimed in claim 1, wherein a CTE of the first inorganic dielectric layer is between 3 ppm/° C. and 5 ppm/° C.

5. The integrated circuit package structure as claimed in claim 1, wherein the material of the first inorganic dielectric layer includes silicon oxide, silicon nitride, silicon carbonitride, silicon oxynitride, silicon carbide, or a combination thereof.

6. The integrated circuit package structure as claimed in claim 1, wherein a CTE of the organic dielectric layer is between 9 ppm/° C. and 25 ppm/° C.

7. The integrated circuit package structure as claimed in claim 1, wherein the material of the organic dielectric layer includes bismaleimide-triazine resin, epoxy resin, phenolic resin, cyanate resin, polycarbonate, silicone elastomer, or a combination thereof.

8. The integrated circuit package structure as claimed in claim 1, wherein a thickness of the first inorganic dielectric layer is less than or equal to 1% of a thickness of the core.

9. The integrated circuit package structure as claimed in claim 1, wherein a thickness of the organic dielectric layer is between 1% and 15% of a thickness of the core.

10. The integrated circuit package structure as claimed in claim 1, wherein the circuit substrate further comprises:
a first redistribution structure disposed on the first surface of the core, wherein the first redistribution structure comprises the first inorganic dielectric layer and a first conductive line disposed on the first inorganic dielectric layer; and
a second redistribution structure disposed on the second surface of the core, wherein the second redistribution structure comprises the organic dielectric layer and a second conductive line disposed on the organic dielectric layer,
wherein the first conductive line has a first width, the second conductive line has a second width, and the second width is greater than the first width.

11. The integrated circuit package structure as claimed in claim 10, wherein a ratio of the second width to the first width is between 2.5 and 100.

12. The integrated circuit package structure as claimed in claim 10, wherein the second redistribution structure further comprises:
a second inorganic dielectric layer disposed between the core and the organic dielectric layer; and
a third conductive line disposed on the second inorganic dielectric layer,
wherein the first inorganic dielectric layer and the second inorganic dielectric layer comprise the same material.

13. The integrated circuit package structure as claimed in claim 12, wherein the third conductive line has a third width.

14. The integrated circuit package structure as claimed in claim 13, wherein a ratio of the second width to the third width is between 2.5 and 100.

15. The integrated circuit package structure as claimed in claim 10, wherein the second redistribution structure further comprises:
a stress-release dielectric layer disposed between the core and the organic dielectric layer; and
a fourth conductive line disposed on the stress-release dielectric layer.

16. The integrated circuit package structure as claimed in claim 15, wherein the fourth conductive line has a fourth width.

17. The integrated circuit package structure as claimed in claim 15, wherein a CTE of the stress-release dielectric layer is between 9 ppm/° C. and 25 ppm/° C.

18. The integrated circuit package structure as claimed in claim 10, further comprising:
a first chip disposed on the first inorganic dielectric layer, wherein a first chip pad of the first chip is directly connected to a first redistribution structure pad of the first redistribution structure; and
a conductive bump disposed on the organic dielectric layer and passing through the solder mask to connect to a second redistribution structure pad of the second redistribution structure.

19. The integrated circuit package structure as claimed in claim 18, further comprising:
a second chip disposed side by side with the first chip and on the first inorganic dielectric layer, wherein a second chip pad of the second chip is directly connected to a third redistribution structure pad of the first redistribution structure, and the first chip is coupled to the second chip via the first redistribution structure.

20. The integrated circuit package structure as claimed in claim 19, further comprising:
a bridge element disposed in the first inorganic dielectric layer and partially overlapping the first chip and the second chip, wherein the first chip is coupled to the second chip via the bridge element.
